(19) United States
(12) Patent Application Publication
(10) Pub. No.: US 2006/0066263 A1
(43) Pub. Date: Mar. 30, 2006

(54) Electro-optical device, method of manufacturing the same, and electronic apparatus

(75) Inventors: Tomoyuki Okuyama, Chino-shi (JP); Hiroyuki Hara, Chino-shi (JP); Mutsumi Kimura, Kyotanabe-shi (JP)

Correspondence Address: OLIFF & BERRIDGE, PLC, P.O. BOX 19928, ALEXANDRIA, VA, 22320, US

(73) Assignees: Seiko Epson Corporation, Tokyo (JP); Ryukoku University, Kyoto-shi (JP)

(21) Appl. No.: 11/213,970

(22) Filed: Aug. 30, 2005

(30) Foreign Application Priority Data
Sep. 24, 2004 (JP) 2004-277322
Sep. 24, 2004 (JP) 2004-277332
Sep. 27, 2004 (JP) 2004-279305
Jun. 9, 2005 (JP) 2005-169724

(51) Int. Cl. H05B 41/36

(52) U.S. Cl. 315/291

(57) ABSTRACT

An electro-optical device which has a program period, a light-emitting period, an erasing period, and a lights-off period in one frame and controls the light-emitting period according to a light emission gray-scale level including a driving transistor that includes a current control terminal, a current input terminal, and a current output terminal, and controls a current amplifying ratio on the basis of a voltage between the current control terminal and the current input terminal, an electro-optical element that is supplied with the driving current from the driving transistor to emit light, a storage capacitor that stores the charge corresponding to the voltage between the current control terminal and the current input terminal of the driving transistor, a constant current source that outputs a constant current that is independent of the light emission gray-scale level, a voltage source that outputs a driving stop signal that turns off the driving transistor, a selection transistor that opens/closes a current path connecting any one of the constant current source and the voltage source with the driving transistor, and a scan line that outputs open/close signals that turn on/off the selection transistor. The program period is a period when the selection transistor is turned on by outputting an open signal to the scan line, and when the constant current flows from the constant current source to the driving transistor through the current path, the charge corresponding to the voltage between the current control terminal and the current input terminal is stored in the storage capacitor. The light-emitting period is a period when the selection transistor is turned off by outputting a close signal to the scan line, and the voltage corresponding to the charge stored in the storage capacitor is supplied between the current control terminal and the current input terminal of the driving transistor to supply the driving current to the electro-optical element. The erasing period is a period when the selection transistor is turned on by outputting the open signal to the scan line, and the driving stop signal is supplied to the driving transistor from the voltage source through the current path to turn off the driving transistor so that the electro-optical element stops emitting light. The lights-off period is a period when the selection transistor is turned off by outputting the close signal to the scan line, and the electro-optical element retains a non-light-emitting state. A time constant of the scan line is set so that signal delay of the open/close signals is 10% or less of a theoretical value.

### BACKGROUND

The present invention relates to an electro-optical device, to a method of manufacturing the same, and to an electronic apparatus.

Recently, research on organic electroluminescent display devices as one example of electro-optical devices has been actively progressing (For example, see Japanese Unexamined Patent Application Publication No. 2004-233522). Since the organic electroluminescent display element has excellent characteristics such as self-emittance, high brightness, high viewing angle, thinness, rapid response, low power consumption, it can be applied to a thin display having a large screen and high-definition by being combined with a polysilicon thin film transistor (TFT) as a driving element.

As the display becomes larger, the effect of the signal delay of various control signals supplied to each pixel increases. This problem is due to the increment of a time constant of a signal line. The increment of the time constant of a signal line is caused by the increment of the length of a signal line for transmitting a control signal or the increment of a parasitic capacitance which is accompanied with the increment of the number of wiring lines and high density necessary for high definition. Since this signal delay deteriorates the display quality of the display, an efficient solution is needed.

### SUMMARY

An advantage of the invention is that it provides an electro-optical device which can prevent display quality from being deteriorated by signal delay and a method of manufacturing the same.

According to an aspect of the invention, an electro-optical device which has a program period, a light-emitting period, an erasing period, and a lights-off period in one frame and controls the light-emitting period according to a light emission gray-scale level, includes a driving transistor that includes a current control terminal, a current input terminal, and a current output terminal, and controls a current amplifying ratio on the basis of a voltage between the current control terminal and the current input terminal; an electro-optical element that is supplied with the driving current from the driving transistor to emit light; a storage capacitor that stores the charge corresponding to the voltage between the current control terminal and the current input terminal of the driving transistor; a constant current source that outputs a constant current that is independent of the light emission gray-scale level; a voltage source that outputs a driving stop signal that turns off the driving transistor; a selection transistor that opens/closes a current path connecting any one of the constant current source and the voltage source with the driving transistor; and a scan line that outputs open/close signals that turn on/off the selection transistor. The program period is a period when the selection transistor is turned on by outputting an open signal to the scan line, and when the constant current flows from the constant current source to the driving transistor through the current path, the charge corresponding to the voltage between the current control terminal and the current input terminal is stored in the storage capacitor. In addition, the light-emitting period is a period when the selection transistor is turned off by outputting a close signal to the scan line, and the voltage corresponding to the charge stored in the storage capacitor is supplied between the current control terminal and the current input terminal of the driving transistor to supply the driving current to the electro-optical element. Furthermore, the erasing period is a period when the selection transistor is turned on by outputting the open signal to the scan line, and the driving stop signal is supplied to the driving transistor from the voltage source through the current path to turn off the driving transistor so that the electro-optical element stops emitting light. In addition, the lights-off period is a period when the selection transistor is turned off by outputting the close signal to the scan line, and the electro-optical element retains a non-light-emitting state. Moreover, a time constant of the scan line is set so that signal delay of the open/close signals is 10% or less of a theoretical value.

Here, the “electro-optical device” is a device including an electro-optical element which emits light by an electric operation or changes the state of light from the outside, and includes a device that self-emits light and controls the passage control of light from the outside. For example, as the electro-optical element, there are an electroluminescent element, a liquid crystal element, an electrophoretic element which includes a dispersion medium dispersing electrophoretic particles, and an active matrix type display device having an electron emission element for bring electrons generated by applying an electric field into contact with a light emitting plate and emitting light.

In the above-mentioned structure, the signal delay is suppressed by adequately setting the time constant (product of capacitance component and resistance component: τ=CR) of the signal line on the basis of the knowledge that allowable range of the signal delay is 10% or less. Accordingly, writing lack of the signal required for the display control can be avoided at a maximum and thus the display quality can be prevented from being deteriorated by the signal delay.

Preferably, the time constant of the scan line is set by increasing/decreasing a resistance component using a thickness and/or a line width of the scan line as a parameter. Further, it is preferable that the time constant of the scan line be set by increasing/decreasing a resistance component using the specific resistance of a material used for forming the scan line as a parameter. The time constant of the scan line can be easily set by adding/subtracting the resistance component using these parameters.

Preferably, the time constant of the scan line is set by increasing/decreasing a capacitance component using a distance between adjacent scan lines as a parameter. Also, it is preferable that the time constant of the scan line be set by increasing/decreasing a capacitance component using a relative dielectric constant of a material used for forming an insulating film arranged above and/or below the scan line as a parameter. Furthermore, it is preferable that the time constant of the scan line be set by increasing/decreasing a capacitance component using a thickness of a material used for forming an insulating film arranged above and/or below the scan line as a parameter. The time constant of the scan line can be easily set by adding/subtracting the capacitance component using these parameters.

According to another aspect of the invention, an electro-optical device which has a program period, a light-emitting period, an erasing period, and a lights-off period in one frame and controls the light-emitting period according to a light emission gray-scale level, includes a driving transistor that includes a current control terminal, a current input terminal, and a current output terminal, and controls a current amplifying ratio on the basis of a voltage between the current control terminal and the current input terminal; an electro-optical element that is supplied with the driving current from the driving transistor to emit light; a storage capacitor that stores the charge corresponding to the voltage between the current control terminal and the current input terminal of the driving transistor; a constant current source that outputs a constant current that is independent of the light emission gray-scale level; a voltage source that outputs a driving stop signal that turns off the driving transistor; a selection transistor that opens/closes a data line connecting any either the constant current source or the voltage source with the driving transistor; and a first scan line that outputs open/close signals that turn on/off the selection transistor. The program period is a period when the selection transistor is turned on by outputting an open signal to the first scan line, and when the constant current flows from the constant current source to the driving transistor through the data line, the charge corresponding to the voltage between the current control terminal and the current input terminal is stored in the storage capacitor. The light-emitting period is a period when the selection transistor is turned off by outputting a close signal to the first scan line, and the voltage corresponding to the charge stored in the storage capacitor is supplied between the current control terminal and the current input terminal of the driving transistor to supply the driving current to the electro-optical element. The erasing period is a period when the selection transistor is turned on by outputting the open signal to the first scan line, and the driving stop signal is supplied to the driving transistor from the voltage source through the current path to turn off the driving transistor so that the electro-optical element stops emitting light. The lights-off period is a period when the selection transistor is turned off by outputting the close signal to the first scan line, and the electro-optical element retains a non-light-emitting state. The first scan line is formed by one or a plurality of wiring layers having a time constant in which the signal delay of the open/close signals is 10% or less of a theoretical value. The current control terminal of the selection transistor is connected to one or a plurality of wiring layers.

The electro-optical device according to the above aspect of the invention further includes a reproduction selection transistor that opens/closes a current path supplying the driving current from the driving transistor to the electro-optical element; and a second scan line that outputs an open/close signal that turns on/off the reproduction selection transistor. The second scan line is formed by one or a plurality of wiring layers having a time constant in which the signal delay of the open/close signals is 10% or less of a theoretical value, and a current control terminal of the reproduction selection transistor is connected to one or a plurality of wiring layers. The signal delay is avoided by forming the second scan line using the wiring layer having low resistance and thus the electro-optical device having high quality can be provided.

In the electro-optical device according to the above aspect of the invention, the data line may be formed by one or a plurality of wiring layers having a time constant in which signal delay of the open/close signals is 10% or less of a theoretical value, and a current output terminal of the driving transistor is connected to one or a plurality of wiring layers. The signal delay is avoided by forming the data line using the wiring layer having low resistance and thus the electro-optical device having high quality can be provided.

In the electro-optical device according to above aspect of the invention, the time constant of the wiring layer is set by increasing/decreasing a resistance component using a thickness and/or a line width of the first scan line, the second scan line, or the data line as a parameter.

Further, in the electro-optical device according to the above aspect of the invention, the time constant of the wiring layer is set by increasing/decreasing a resistance component using the specific resistance of a material used for forming the first scan line, the second scan line, or the data line as a parameter.

Furthermore, in the electro-optical device according to the above aspect of the invention, the time constant of the wiring layer is set by increasing/decreasing a capacitance component using a distance between adjacent first scan lines, adjacent second scan lines, or adjacent data lines as a parameter.

Moreover, in the electro-optical device according to the above aspect of the invention, the time constant of the wiring layer is set by increasing/decreasing a capacitance component using a relative dielectric constant of a material used for forming an insulating film arranged above and/or below the first scan line, the second scan line, or the data line as a parameter.

Furthermore, in the electro-optical device according to the above aspect of the invention, the time constant of the wiring layer is set by increasing/decreasing a capacitance component using a thickness of a material used for forming an insulating film arranged above and/or below the first scan line, the second scan line, or the data line as a parameter.

According to still another aspect of the invention, an electro-optical device has a driving transistor that includes a current control terminal, a current input terminal, and a current output terminal, and controls a current amplifying ratio on the basis of a voltage between the current control terminal and the current input terminal; an electro-optical element that is supplied with the driving current from the driving transistor to emit light; a storage capacitor that stores the charge corresponding to the voltage between the current control terminal and the current input terminal of the driving transistor; a constant current source that outputs a constant current independent of the light emission gray-scale level; a voltage source that outputs a driving stop signal that turns off the driving transistor; a selection transistor that opens/closes a current path connecting any one of the constant current source and the voltage source with the driving transistor; and a scan line that outputs open/close signals that turn on/off the selection transistor. In the above mentioned electro-optical device, one frame has a program period, a light-emitting period, an erasing period, and a lights-off period, and the light-emitting period is controlled according to a light emission gray-scale level, the program period is a period when the selection transistor is turned on by outputting an open signal to the scan line, and when the constant current flows from the constant current source to the driving transistor through the current path, the charge corresponding to the voltage between the current control terminal and the current input terminal is stored in the storage capacitor, the light-emitting period is a period when the selection transistor is turned off by outputting a close signal to the scan line, and the voltage corresponding to the charge stored in the storage capacitor is supplied between the current control terminal and the current input terminal of the driving transistor to supply the driving current to the electro-optical element, the erasing period is a period when the selection transistor is turned on by outputting the open signal to the scan line, and the driving stop signal is supplied to the driving transistor from the voltage source through the current path to turn off the driving transistor so that the electro-optical element stops emitting light, the lights-off period is a period when the selection transistor is turned off by outputting the close signal to the scan line, and the electro-optical element retains a non-light-emitting state, and a time constant of the scan line is set so that the signal delay of the open/close signals is 10% or less of a theoretical value. A method of manufacturing an electro-optical device includes forming the driving transistor on a temporary substrate; forming a signal line which connects the driving transistor with the electro-optical element on a wiring substrate; and bonding the driving transistor to the wiring substrate to connect the driving transistor with the signal line.

Preferably, the electro-optical device is an organic electroluminescent element. Accordingly, it is possible to drive the organic electroluminescent element with high definition.

According to the above aspect of the invention, there is an electronic apparatus manufactured by the manufacturing method according to the invention or the electro-optical device according to the invention. Here, the electronic apparatus is a general apparatus having a predetermined function and the structure thereof is not specially limited. The electronic apparatus includes, for example, an IC card, a mobile phone, a video camera, a personal computer, a head mount display, a rear-type or front-type projector, a facsimile having a display function, a finer of a digital camera, a portable television, a PDA, and an electronic notebook. Thereby, an electronic apparatus having high display quality can be obtained.

An advantage of the invention is that it provides an electro-optical device which can prevent display quality from being deteriorated by signal delay and a method of manufacturing the same.

According to an aspect of the invention, an electro-optical device which has a program period, a light-emitting period, an erasing period, and a lights-off period in one frame and controls the light-emitting period according to a light emission gray-scale level, includes a driving transistor that includes a current control terminal, a current input terminal, and a current output terminal, and controls a current amplifying ratio on the basis of a voltage between the current control terminal and the current input terminal; an electro-optical element that is supplied with the driving current from the driving transistor to emit light; a storage capacitor that stores the charge corresponding to the voltage between the current control terminal and the current input terminal of the driving transistor; a constant current source that outputs a constant current that is independent of the light emission gray-scale level; a voltage source that outputs a driving stop signal that turns off the driving transistor; a selection transistor that opens/closes a current path connecting any one of the constant current source and the voltage source with the driving transistor; and a scan line that outputs open/close signals that turn on/off the selection transistor. The program period is a period when the selection transistor is turned on by outputting an open signal to the scan line, and when the constant current flows from the constant current source to the driving transistor through the current path, the charge corresponding to the voltage between the current control terminal and the current input terminal is stored in the storage capacitor. In addition, the light-emitting period is a period when the selection transistor is turned off by outputting a close signal to the scan line, and the voltage corresponding to the charge stored in the storage capacitor is supplied between the current control terminal and the current input terminal of the driving transistor to supply the driving current to the electro-optical element. Furthermore, the erasing period is a period when the selection transistor is turned on by outputting the open signal to the scan line, and the driving stop signal is supplied to the driving transistor from the voltage source through the current path to turn off the driving transistor so that the electro-optical element stops emitting light. In addition, the lights-off period is a period when the selection transistor is turned off by outputting the close signal to the scan line, and the electro-optical element retains a non-light-emitting state. Moreover, a time constant of the scan line is set so that signal delay of the open/close signals is 10% or less of a theoretical value.

Here, the “electro-optical device” is a device including an electro-optical element which emits light by an electric operation or changes the state of light from the outside, and includes a device that self-emits light and controls the passage control of light from the outside. For example, as the electro-optical element, there are an electroluminescent element, a liquid crystal element, an electrophoretic element which includes a dispersion medium dispersing electrophoretic particles, and an active matrix type display device having an electron emission element for bring electrons generated by applying an electric field into contact with a light emitting plate and emitting light.

In the above-mentioned structure, the signal delay is suppressed by adequately setting the time constant (product of capacitance component and resistance component: τ=CR) of the signal line on the basis of the knowledge that allowable range of the signal delay is 10% or less. Accordingly, writing lack of the signal required for the display control can be avoided at a maximum and thus the display quality can be prevented from being deteriorated by the signal delay.

Preferably, the time constant of the scan line is set by increasing/decreasing a resistance component using a thickness and/or a line width of the scan line as a parameter. Further, it is preferable that the time constant of the scan line be set by increasing/decreasing a resistance component using the specific resistance of a material used for forming the scan line as a parameter. The time constant of the scan line can be easily set by adding/subtracting the resistance component using these parameters.

Preferably, the time constant of the scan line is set by increasing/decreasing a capacitance component using a distance between adjacent scan lines as a parameter. Also, it is preferable that the time constant of the scan line be set by increasing/decreasing a capacitance component using a relative dielectric constant of a material used for forming an insulating film arranged above and/or below the scan line as a parameter. Furthermore, it is preferable that the time constant of the scan line be set by increasing/decreasing a capacitance component using a thickness of a material used for forming an insulating film arranged above and/or below the scan line as a parameter. The time constant of the scan line can be easily set by adding/subtracting the capacitance component using these parameters.

According to another aspect of the invention, an electro-optical device which has a program period, a light-emitting period, an erasing period, and a lights-off period in one frame and controls the light-emitting period according to a light emission gray-scale level, includes a driving transistor that includes a current control terminal, a current input terminal, and a current output terminal, and controls a current amplifying ratio on the basis of a voltage between the current control terminal and the current input terminal; an electro-optical element that is supplied with the driving current from the driving transistor to emit light; a storage capacitor that stores the charge corresponding to the voltage between the current control terminal and the current input terminal of the driving transistor; a constant current source that outputs a constant current that is independent of the light emission gray-scale level; a voltage source that outputs a driving stop signal that turns off the driving transistor; a selection transistor that opens/closes a data line connecting any either the constant current source or the voltage source with the driving transistor; and a first scan line that outputs open/close signals that turn on/off the selection transistor. The program period is a period when the selection transistor is turned on by outputting an open signal to the first scan line, and when the constant current flows from the constant current source to the driving transistor through the data line, the charge corresponding to the voltage between the current control terminal and the current input terminal is stored in the storage capacitor. The light-emitting period is a period when the selection transistor is turned off by outputting a close signal to the first scan line, and the voltage corresponding to the charge stored in the storage capacitor is supplied between the current control terminal and the current input terminal of the driving transistor to supply the driving current to the electro-optical element. The erasing period is a period when the selection transistor is turned on by outputting the open signal to the first scan line, and the driving stop signal is supplied to the driving transistor from the voltage source through the current path to turn off the driving transistor so that the electro-optical element stops emitting light. The lights-off period is a period when the selection transistor is turned off by outputting the close signal to the first scan line, and the electro-optical element retains a non-light-emitting state. The first scan line is formed by one or a plurality of wiring layers having a time constant in which the signal delay of the open/close signals is 10% or less of a theoretical value. The current control terminal of the selection transistor is connected to one or a plurality of wiring layers.

The electro-optical device according to the above aspect of the invention further includes a reproduction selection transistor that opens/closes a current path supplying the driving current from the driving transistor to the electro-optical element; and a second scan line that outputs an open/close signal that turns on/off the reproduction selection transistor. The second scan line is formed by one or a plurality of wiring layers having a time constant in which the signal delay of the open/close signals is 10% or less of a theoretical value, and a current control terminal of the reproduction selection transistor is connected to one or a plurality of wiring layers. The signal delay is avoided by forming the second scan line using the wiring layer having low resistance and thus the electro-optical device having high quality can be provided.

In the electro-optical device according to the above aspect of the invention, the data line may be formed by one or a plurality of wiring layers having a time constant in which signal delay of the open/close signals is 10% or less of a theoretical value, and a current output terminal of the driving transistor is connected to one or a plurality of wiring layers. The signal delay is avoided by forming the data line using the wiring layer having low resistance and thus the electro-optical device having high quality can be provided.

In the electro-optical device according to above aspect of the invention, the time constant of the wiring layer is set by increasing/decreasing a resistance component using a thickness and/or a line width of the first scan line, the second scan line, or the data line as a parameter.

Further, in the electro-optical device according to the above aspect of the invention, the time constant of the wiring layer is set by increasing/decreasing a resistance component using the specific resistance of a material used for forming the first scan line, the second scan line, or the data line as a parameter.

Furthermore, in the electro-optical device according to the above aspect of the invention, the time constant of the wiring layer is set by increasing/decreasing a capacitance component using a distance between adjacent first scan lines, adjacent second scan lines, or adjacent data lines as a parameter.

Moreover, in the electro-optical device according to the above aspect of the invention, the time constant of the wiring layer is set by increasing/decreasing a capacitance component using a relative dielectric constant of a material used for forming an insulating film arranged above and/or below the first scan line, the second scan line, or the data line as a parameter.

Furthermore, in the electro-optical device according to the above aspect of the invention, the time constant of the wiring layer is set by increasing/decreasing a capacitance component using a thickness of a material used for forming an insulating film arranged above and/or below the first scan line, the second scan line, or the data line as a parameter.

According to still another aspect of the invention, an electro-optical device has a driving transistor that includes a current control terminal, a current input terminal, and a current output terminal, and controls a current amplifying ratio on the basis of a voltage between the current control terminal and the current input terminal; an electro-optical element that is supplied with the driving current from the driving transistor to emit light; a storage capacitor that stores the charge corresponding to the voltage between the current control terminal and the current input terminal of the driving transistor; a constant current source that outputs a constant current independent of the light emission gray-scale level; a voltage source that outputs a driving stop signal that turns off the driving transistor; a selection transistor that opens/closes a current path connecting any one of the constant current source and the voltage source with the driving transistor; and a scan line that outputs open/close signals that turn on/off the selection transistor. In the above mentioned electro-optical device, one frame has a program period, a light-emitting period, an erasing period, and a lights-off period, and the light-emitting period is controlled according to a light emission gray-scale level, the program period is a period when the selection transistor is turned on by outputting an open signal to the scan line, and when the constant current flows from the constant current source to the driving transistor through the current path, the charge corresponding to the voltage between the current control terminal and the current input terminal is stored in the storage capacitor, the light-emitting period is a period when the selection transistor is turned off by outputting a close signal to the scan line, and the voltage corresponding to the charge stored in the storage capacitor is supplied between the current control terminal and the current input terminal of the driving transistor to supply the driving current to the electro-optical element, the erasing period is a period when the selection transistor is turned on by outputting the open signal to the scan line, and the driving stop signal is supplied to the driving transistor from the voltage source through the current path to turn off the driving transistor so that the electro-optical element stops emitting light, the lights-off period is a period when the selection transistor is turned off by outputting the close signal to the scan line, and the electro-optical element retains a non-light-emitting state, and a time constant of the scan line is set so that the signal delay of the open/close signals is 10% or less of a theoretical value. A method of manufacturing an electro-optical device includes forming the driving transistor on a temporary substrate; forming a signal line which connects the driving transistor with the electro-optical element on a wiring substrate; and bonding the driving transistor to the wiring substrate to connect the driving transistor with the signal line.

Preferably, the electro-optical device is an organic electroluminescent element. Accordingly, it is possible to drive the organic electroluminescent element with high definition.

According to the above aspect of the invention, there is an electronic apparatus manufactured by the manufacturing method according to the invention or the electro-optical device according to the invention. Here, the electronic apparatus is a general apparatus having a predetermined function and the structure thereof is not specially limited. The electronic apparatus includes, for example, an IC card, a mobile phone, a video camera, a personal computer, a head mount display, a rear-type or front-type projector, a facsimile having a display function, a finer of a digital camera, a portable television, a PDA, and an electronic notebook. Thereby, an electronic apparatus having high display quality can be obtained.

### BRIEF DESCRIPTION OF THE DRAWINGS

The invention will be described with reference to the accompanying drawings, wherein like numbers reference like elements, and wherein:

FIG. 1 is a block diagram showing the electric structure of an organic electroluminescent display device;

FIG. 2 is a block diagram showing circuit structure of a display panel;

FIG. 3 is a circuit diagram of a pixel;

FIG. 4 is a time chart illustrating a series of operations of a program period, a light-emitting period, an erasing period, and a lights-off period of the pixel;

FIG. 5 is a view illustrating the structure of one frame (sub-frame);

FIG. 6 is a view illustrating the content of signal delay;

FIG. 7 is a view illustrating the content of signal delay;

FIG. 8 is a process view illustrating a method of manufacturing an organic electroluminescent display device;

FIG. 9 is a process view illustrating the method of manufacturing the organic electroluminescent display device;

FIG. 10 is a cross-sectional view showing processes of manufacturing the organic electroluminescent display device;

FIG. 11 is a cross-sectional view showing processes of manufacturing the organic electroluminescent display device;

FIG. 12 is a cross-sectional view of a wiring layer of a single layer structure;

FIG. 13 is a wiring layout diagram of the single layer structure;

FIG. 14 is a cross-sectional view of a wiring layer of a double layer structure;

FIG. 15 is a wiring layout diagram of the double layer structure;

FIG. 16 is a process view illustrating a method of manufacturing an organic electroluminescent display device;

FIG. 17 is a process view illustrating a method of manufacturing an organic electroluminescent display device;

FIG. 18 is a process view illustrating a method of manufacturing an organic electroluminescent display device;

FIG. 19 is a process view illustrating a method of manufacturing an organic electroluminescent display device;

FIG. 20 is a perspective view of a television including the electro-optical device;

FIG. 21 is a perspective view of a roll-up type television including the electro-optical device;

FIG. 22 is a perspective view of a mobile phone including the electro-optical device;

FIG. 23 is a perspective view of a video camera including the electro-optical device; and

FIG. 24 is a perspective view of a personal computer including the electro-optical device.

### DETAILED DESCRIPTION OF EMBODIMENTS

An electro-optical device according to an embodiment of the invention will be described. Hereinafter, an organic electroluminescent display device will be described as an example of the electro-optical device.

### First Embodiment

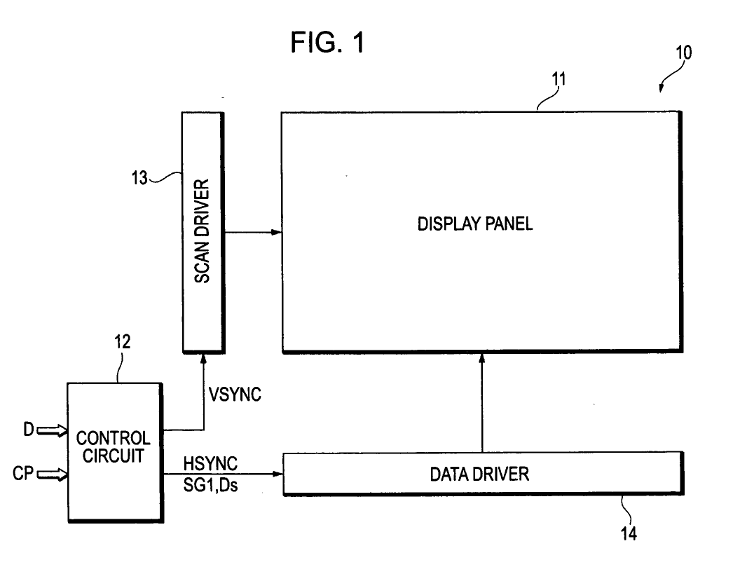

FIG. 1 is a block diagram showing the electric structure of an organic electroluminescent display device. The organic electroluminescent display device 10 shown in FIG. 1 includes a display panel 11, a control circuit 12, a scan driver 13, and a data driver 14.

The control circuit 12, the scan driver 13, and the data driver 14 may be formed of independent electronic components. For example, the control circuit 12, the scan driver 13, and the data driver 14 may be a one-chip semiconductor integrated circuit device. Also, a portion of or all of the control circuit 12, the scan driver 13, and the data driver 14 may be formed of an integral electronic component. For example, the control circuit 12, the scan driver 13, and the data driver 14 may be integrally formed in the display panel 11. All of or a portion of the control circuit 12, the scan driver 13, and the data driver 14 may be formed of a programmable IC chip and the function thereof may be carried out by software programs written in the IC chip.

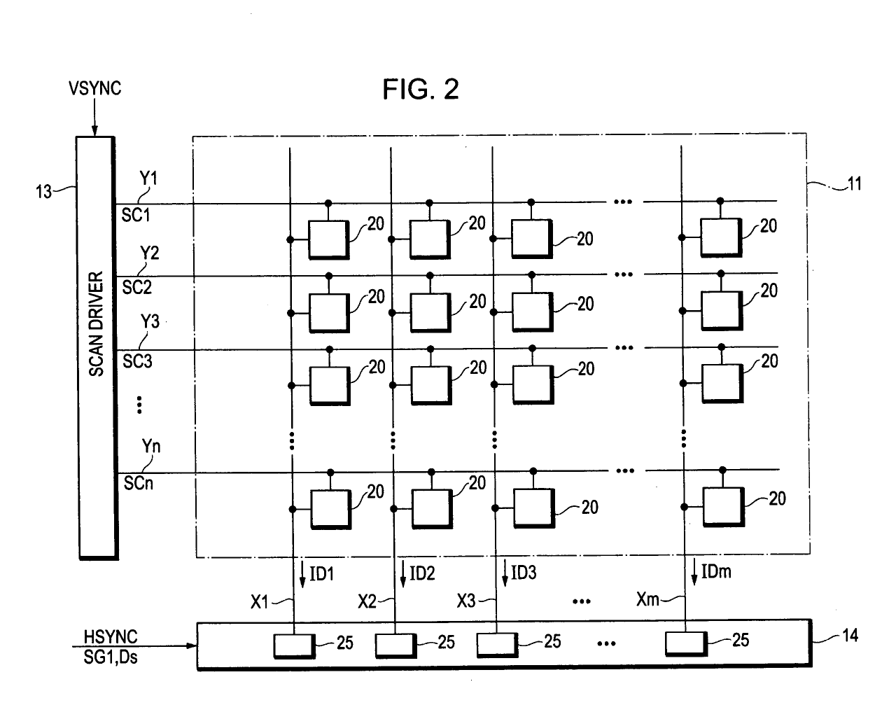

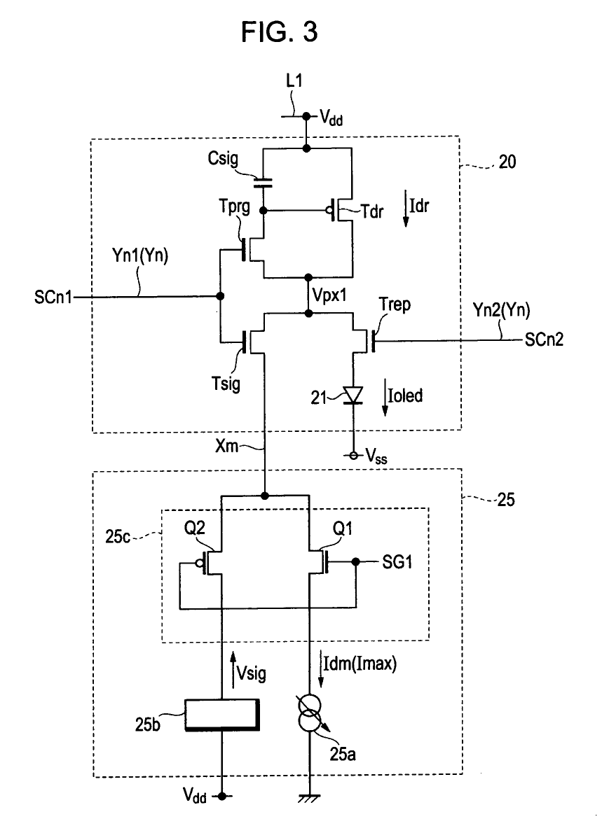

As shown in FIG. 2, a plurality of data lines X1 to Xm (m is a natural number) extending in a column direction and a plurality of scan lines Y1 to Yn (n is a natural number) extending in a row direction are arranged on the display panel 11. In addition, the display panel 11 includes a plurality of pixels 20 arranged at positions corresponding to intersections of the plurality of the data lines X1 to Xm and the plurality of the scan lines Y1 to Yn. That is, each of the pixels 20 is arranged in a matrix among the plurality of the data lines X1 to Xm extending in the column direction and the plurality of the scan lines Y1 to Yn extending in the row direction, and is electrically connected thereto. Each of the pixels 20 has an organic electroluminescent element 21 (See FIG. 3) including a light-emitting layer consisting of an organic material.

FIG. 3 is a circuit diagram showing the electrical structure of the pixel 20. As shown in FIG. 3, the pixel 20 includes a driving transistor Tdr, a program transistor Tprg, a program selection transistor Tsig, reproduction selection transistor Trep, and a storage capacitor Csig. The driving transistor Tdr is composed of a P-channel TFT. The program transistor Tprg, the program selection transistor Tsig, and the reproduction selection transistor Trep are composed of N-channel TFTs.

The drain of the driving transistor Tdr is connected to a positive electrode of the organic electroluminescent element 21 through the reproduction selection transistor Trep. A negative electrode of the organic electroluminescent element 21 is grounded. Furthermore, the drain of the driving transistor Tdr is connected to the data line Xm through the program selection transistor Tsig. Furthermore, the source of driving transistor Tdr is connected to a power supply line L1 and the power supply line L1 is supplied with a driving voltage Vdd for driving the organic electroluminescent element 21. In addition, the gate of the driving transistor Tdr is connected to a first electrode of the storage capacitor Csig and a second electrode of the storage capacitor Csig is connected to the power supply line L1. The program transistor Tprg is connected between the gate and the drain of the driving transistor Tdr.

The gates of the program selection transistor Tsig and the program transistor Tprg are connected to a first scan line Yn1 composing the scan line Yn. Also, the program selection transistor Tsig and the program transistor Tprg are turned on in response to a first scan signal SCn1 having a H level input from the first scan line Yn1, and are turn off in response to a first scan signal SCn1 having a L level. The gate of the reproduction selection transistor Trep is connected to a second scan line Yn2 composing the scan line Yn. Furthermore, the reproduction selection transistor Trep is turned on in response to a second scan signal SCn2 having a H level input from the second scan line Yn2 and is turned off in response to the second scan signal SCn2 having a L level.

Next, the organic electroluminescent element 21 emits light with a brightness according to the size of a driving current Idr (supplying current Ioled) supplied through the driving transistor Tdr.

Next, the operation of the pixel 20 will be briefly described.

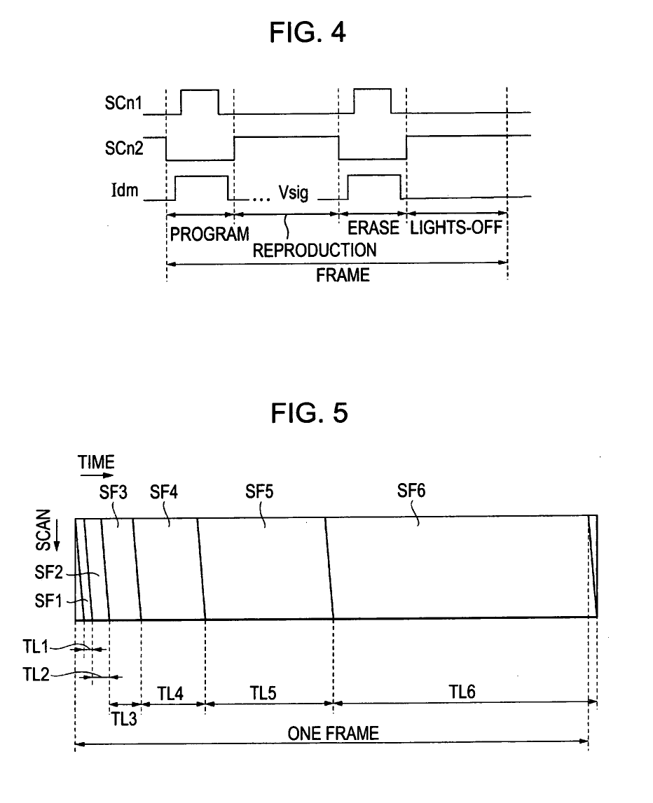

FIG. 4 is a time chart illustrating a series of operations such as a program period, a light-emitting period, an erasing period, and a lights-off period of the pixel 20.

(Program Period)

Here, if the first scan signal SCn1 having the H level is output, the program transistor Tprg and the program selection transistor Tsig are turned on. At this time, the second scan signal SCn2 having the L level is output and thus the reproduction selection transistor Trep is turned off. At this time, the data current Idm is supplied to the data line Xm. Furthermore, the driving transistor Tdr is diode-connected by turning on the program transistor Tprg. As a result, the data current Idm flows through a path including the driving transistor Tdr, the program selection transistor Tsig, and the data line Xm. At this time, the charge corresponding to the potential of the gate of the driving transistor Tdr is stored in the storage capacitor Csig.

(Light-Emitting Period)

From this state, if the first scan signal SCn1 becomes the L level and the second scan signal SCn2 becomes the H level, the program transistor Tprg and the program selection transistor Tsig are turned off and the reproduction selection transistor Trep is turned on. At this time, since the state of stored charge in the storage capacitor Csig is not changed, the gate potential of the driving transistor Tdr is maintained at a certain voltage when the data current Idm flows. Accordingly, a driving current Idr (supplying current Ioled) having a magnitude according to the gate voltage of the driving transistor Tdr flows between the source and the drain of the driving transistor Tdr. In more detail, the supplying current Ioled flows through a path including the driving transistor Tdr, the reproduction selection transistor Trep, and the organic electroluminescent element 21. Consequently, the organic electroluminescent element 21 emits light with a brightness according to the supplying current Ioled (data current Idm). Moreover, at this time, since the current path of the program period is different from that of the light-emitting period and the load characteristics of the driving transistor Tdr are changed and thus the operation point is changed, the change ratios of the supplying current Ioled to every data current Idm are different from each other.

(Erasing Period)

If the organic electroluminescent element 21 emits light and a predetermined period passes, the second scan signal SCn2 becomes the L level and the reproduction selection transistor Trep is turned off. At this time, since the supplying current Ioled is not supplied, the organic electroluminescent element 21 stops emitting light. Subsequently, if the first scan signal SCn1 becomes the H level, the program transistor Tprg and the program selection transistor Tsig are turned on. At this time, a lights-off signal Vsig (=power supply voltage Vdd) is supplied to the data line Xm as a drive stop signal. At this time, the lights-off signal Vsig (=Vdd) is supplied to the first electrode of the storage capacitor Csig. The gate and the source of the driving transistor Tdr become the same potential and thus the driving transistor Tdr is turned off.

(Lights-Off Period)

From this state, if the first scan signal SCn1 becomes the L level and the second scan signal SCn2 becomes the H level, the program transistor Tprg and the program selection transistor Tsig are turned off and the reproduction selection transistor Trep is turned on. At this time, since the potential of the first electrode of the storage capacitor Csig is equal to that of the source of the driving transistor Tdr, the driving transistor Tdr is maintained in the OFF state. Accordingly, since the supplying current Ioled does not flow, the organic electroluminescent element 21 does not emit light until the next program period.

Consequently, the data current Idm is always maintained constant, and, if the light-emitting period is changed (the lights-off period is changed), the brightness of the organic electroluminescent element 21 can be controlled by the constant data current Idm. That is, since the load characteristics of the driving transistor Tdr are changed and thus the operation point is changed, a gray-scale level can be controlled without considering the change ratio of the supplying current Ioled to every data current Idm.

In the present embodiment, the data driver 14 to be described below outputs the constant data current Idm regardless of gray-scale data, and outputs the lights-off signal Vsig (=Vdd). Moreover, the scan driver 13 to be described below also generates the first scan signal SCn1 and the second scan signal SCn2 for setting the erasing period and the lights-off period on the basis of the gray-scale data.

(Control Circuit)

An image signal (gray-scale data) D and a clock pulse CP for displaying an image on the display panel 11 are input to the control circuit 12 from an external device (not shown). In the present embodiment, the control circuit 12 corrects the image signal (gray-scale data) D of each of the pixels 20 output to the data driver 14 to the largest gray-scale data and outputs the largest gray-scale data as reference gray-scale data Ds. Here, if the gray-scale data are composed of gray-scale levels of 0 to 83, the reference gray-scale data becomes the gray-scale data D of a gray-scale level 83. Accordingly, the data driver 14 outputs the data current Imax on the basis of the reference gray-scale data Ds (gray-scale data of a gray-scale level 63) to the data lines X1 to Xm regardless of gray-scale data D input from the external device and then allows the organic electroluminescent element 21 of each of the pixels 20 to emit light as brightly as possible. Thus, although the organic electroluminescent element 21 emits light on the basis of the reference gray-scale data Ds, the control circuit 12 controls the light-emitting period so as to have the brightness according to the image signal (gray-scale data).

In detail, the control circuit 12 divides one frame into a plurality of sub-frames and generates control data allowing each of the sub-frames to emit light or stop emitting light on the basis of the image signal D of each of the pixels 20. In the present embodiment, as shown in FIG. 5, in order to express halftones by use of 64 gray-scale levels, one frame is divided into first to sixth sub-frames SF1 to SF6. The periods TL1 to TL6 of the first to sixth sub-frames SF1 to SF6 are sequentially set to 1, 2, 4, 8, 16, and 32 from the first sub-frame SF1. That is, the periods TL1 to TL6 are set to the following ratio:
TL1:TL2:TL3:TL4:TL5:TL6=1:2:4:8:16:32

If the gray-scale data has a gray-scale level 63, all the first to sixth sub-frames SF1 to SF6 are selected and the light is emitted during the light-emitting period T (=TL1+TL2+TL3+TL4+TL5+TL6) so that each of the pixels 20 emits light with the brightness corresponding the gray-scale data D of a gray-scale level 63. If the gray-scale data has a gray-scale level 31, the first to fifth sub-frames SF1 to SF5 are selected and the light is emitted during the light-emitting period T (=TL1+TL2+TL3+TL4+TL5) so that each of the pixels 20 emits light with the brightness of the gray-scale level 31. If the gray-scale data D has a gray-scale level 12, the third and fourth sub-frames SF3 and SF4 are selected and the light is emitted during the light-emitting period T (=TL3+TL4) so that each of the pixels 20 emits light with the brightness of the gray-scale level 12. That is, the largest data current Imax corresponding to the gray-scale level 63 is supplied to the data lines X1 to Xm and the light-emitting period T is changed according to the gray-scale data D so that each of the pixels 20 emits light with the brightness corresponding to the gray-scale data D.

For this reason, the control circuit 12 generates the control data of the sub-frame that the light is emitted and the control data of the sub-frame that the light is not emitted (turned off) on the basis of the gray-scale data D of the pixel 20 for every pixel 20. Furthermore, the control circuit 12 outputs a control signal SG1 for determining whether the corresponding sub-frame is in the light-emitting period or the lights-off period to the data driver 14 on the basis of the control data obtained from each of the pixels 20, when scanning the scan lines Y1 to Yn for each of the sub-frames SF1 to SF6. The control circuit 12 outputs the control signal SG1 having the H level when the corresponding sub-frame is in the light-emitting period and outputs the control signal SG1 having the L level when the corresponding sub-frame is in the lights-off period in each of the sub-frames SF1 to SF6.

The control circuit 12 generates a vertical synchronizing signal VSYNC for determining timing that sequentially selects each of the scan lines Y1 to Yn for each of the first to sixth sub-frames SF1 to SF6 of one frame on the basis of the clock pulse CP and outputs it to the scan driver 13. Furthermore, the control circuit 12 generates a horizontal synchronizing signal HSYNC for determining a timing that outputs the reference gray-scale data and the control signal SG1 corresponding to each of the data lines X1 to Xm on the basis of the clock pulse CP and outputs it to the data driver 14.

(Scan Driver)

The scan driver 13 is connected to each of the scan lines Y1 to Yn. The scan driver 13 appropriately selects one of the scan lines Y1 to Yn to select a group of the pixels 20 of one row on the basis of the vertical synchronizing signal VSYNC, in each of the sub-frames SF1 to SF6 of one frame. The scan lines Y1 to Yn are composed of first scan lines Y11 to Yn1 and second scan lines Y12 to Yn2. Furthermore, the scan driver 13 supplies first scan signals SC11 to SCn1 to the program transistor Tprg and the program selection transistor Tsig of the pixel 20 through the first scan lines Y11 to Yn1, in each of the sub-frames SF1 to SF6. Furthermore, the scan driver 13 supplies second scan signals SC12 to SCn2 to the reproduction selection transistor Trep of the pixel 20 through the second scan lines Y12 to Yn2, in each of the sub-frames SF1 to SF6.

(Data Driver)

The horizontal synchronizing signal HSYNC, the reference gray-scale data Ds, and the control signal SG1 are input to the data driver 14 from the control circuit 12. The data driver 14 includes single line driving circuits 25 corresponding to the data lines X1 to Xm, and the corresponding reference gray-scale data Ds is sequentially input to each of the single line driving circuits 25 in synchronization with the horizontal synchronizing signal HSYNC. As shown in FIG. 3, each of the single line driving circuits 25 includes a data current generating circuit 25a, a lights-off signal generating circuit (driving stop signal generating circuit) 25b, and a switching circuit 25c. The data current generating circuit 25a generates data current on the basis of the reference gray-scale data Ds output from the control circuit 12. Each of the data current generating circuits 25a has a digital/analog converting circuit, and the digital/analog converting circuit converts, for example, the 8-bit gray-scale data and then generates the analog current of gray-scale levels of 0 to 63 as the data currents Id1 to Idm. Also, in the present embodiment, each of the single line driving circuits 25 is supplied with the reference gray-scale data Ds having the same value from the control circuit 12. In more detail, the reference gray-scale data Ds output from the control circuit 12 to the data current generating circuits 25a of the single line driving circuits 25 have the largest value (largest gray-scale data D). Accordingly, each of the single line driving circuits 25 generates the data currents Id1 to Idm (=Imax) having the same largest current value.

In the present embodiment, the driving voltage Vdd supplied to the power supply line L1 is applied to the lights-off signal generating circuit 25b and the lights-off signal generating circuit 25b outputs the driving voltage Vdd as the lights-off signal Vsig.

Each of the switching circuits 25c has a first switch Q1 and a second switch Q2. The first switch Q1 is connected between the data line Xm and the data current generating circuit 25a. In the present embodiment, the first switch Q1 is composed of an N-channel FET and the control signal SG1 is input to the gate thereof from the control circuit 12. When the control signal SG1 having the H level is input, the first switches Q1 of the single line driving circuits 25 are turned on and output the data currents Id1 to Idm (=Imax) from the data current generating circuits 25a to the corresponding data lines X1 to Xm. In contrast, when the control signal SG1 having the L level is input, the first switches Q1 of the single line driving circuits 25 are turned off and cut ting off the supply of the data currents Id1 to Idm (=Imax) to the corresponding data lines X1 to Xm.

The second switch Q2 is connected between the data line Xm and the lights-off signal generating circuit 25b. In the present embodiment, the second switch Q2 is composed of a P-channel FET and the control signal SG1 is input to the gate thereof from the control circuit 12. When the control signal SG1 having the L level is input, the second switches Q2 of the single line driving circuits 25 are turned on and output the lights-off signals Vsig input from the lights-off signal generating circuits 25b to the corresponding data lines X1 to Xm. In contrast, when the control signal SG1 having the H level is input, the second switches Q2 of the single line driving circuits 25 are turned off and cut ting off the supply of the lights-off signals Vsig to the corresponding data lines X1 to Xm.

Next, the operation of the organic electroluminescent display device 10 having the above-mentioned structure will be described.

The image data D of one frame is input to the control circuit 12. The control circuit 12 generates the control data of the sub-frame that the light is emitted and the control data of the sub-frame that the light is not emitted in the first to sixth sub-frames SF1 to SF6 on the basis of the image data D of one frame with respect to each of the pixels 20.

Next, the control circuit 12 outputs the vertical synchronizing signal VSYNC to the scan driver 13 and outputs the horizontal synchronizing signal HSYNC to the data driver 14. The scan driver 13 sequentially generates the first scan signals SC 11 to SCn1 and the second scan signals SC12 to SCn2 for the first sub-frame SF1 on the basis of the vertical synchronizing signal VSYNC and sequentially selects the scan lines Y1 to Yn.

On the other hand, whenever each of the scan lines Y1 to Yn is selected, the data driver 14 receives from the control circuit 12 the reference gray-scale data Ds and the control signal SG1 controlling whether the light is emitted in the period TL1 of the first sub-frame SF1 for each pixel 20 on the selected scan line. The data current generating circuit 25a of each of the single line driving circuits 25 generates the data current Imax having the same current value on the basis of the reference gray-scale data Ds. Furthermore, any one of the control signal SG1 having the H level that allows the pixels 20 to emit light and the control signal SG1 having the L level that allows pixels 21 not to emit light is input to the switching circuits 25c of the single line driving circuits 25. The data line of the pixel 20 which emits light is supplied with the data current Imax and the data line of the pixel 20 which does not emit light is supplied with the lights-off signal Vsig.

If the data current Imax is supplied to the pixel 20 which emits light and the lights-off signal Vsig is supplied to the pixel 20 the pixel 20 which does not emit light, the scan driver 13 turns on the reproduction selection transistor Trep on the basis of the second scan signal. The organic electroluminescent element 21 of the pixel 20, which is supplied with the data current Imax on the basis of the ON state of the reproduction selection transistor Trep, is supplied with the driving current Idr (supplying current Ioled) and thus emits light. Since the driving transistor Tdr is in the OFF state, the organic electroluminescent element 21 of the pixel 20, which is supplied with the lights-off signal Vsig, is not supplied with the driving current Idr (supplying current Ioled) and thus does not emit light. Furthermore, this state is maintained until the next second sub-frame SF2 is selected.

If the next scan line is selected, the scan driver 13 performs the above-mentioned operation for each of the pixels 20 on the newly selected scan line and each of the pixels 20 is supplied with any one of the data current Imax and the lights-off signal Vsig from the data driver 14 on the basis of the control signal SG1. Furthermore, each of the pixels 20 emits light or stops emitting light on the basis of the supplied data current Imax or lights-off signal Vsig.

If the supply of the data current Imax or the lights-off signal Vsig to each of the pixels 20 on the final scan line of the first sub-frame SF1 is completed, the scan driver 13 sequentially generates the first scan signals SC11 to SCn1 and the second scan signals SC12 to SCn2 for the second sub-frame and sequentially selects the scan lines Y1 to Yn. On the other hand, the control circuit 12 outputs the reference gray-scale data Ds and the control signal SG1 in the second sub-frame SF2 of each of the pixels 20 on the selected scan line, as mentioned above. Whenever the scan line is selected, the data driver 14 supplies the data current Imax or the lights-off signal Vsig on the basis of the control signal SG1 with respect to each of the pixels 20 on the selected scan line. Furthermore, each of the pixels 20 on the selected scan line emits light or stops emitting light on the basis of the supplied data current Imax or the lights-off signal Vsig, as mentioned above.

Hereinafter, the above-mentioned operation is repeated in the third sub-frame SF3 to the sixth sub-frame SF6 and the image of one frame is exhibited by each of the pixels 20 of the display panel 11. Furthermore, if the image display operation of one frame is completed, the image display operation for the next one frame is performed in the similar way.

Accordingly, for example, if the gray-scale data D has a gray-scale level 63, the pixel 20 emits light in all the first to sixth frames SF1 to SF6 on the basis of the supplied data current Imax and the light-emitting period T becomes T=TL1+TL2+TL3+TL4+TL5+TL6. Furthermore, if the gray-scale data D has a gray-scale level 15, the pixel 20 emits light in the first to fourth frames SF1 to SF4 on the basis of the supplied data current Imax and stop emitting the light in the fifth and sixth sub-frames SF5 and SF6. In this case, the light-emitting period T becomes T=TL1+TL2+TL3+TL4. In addition, if the gray-scale data D has a gray-scale level 3, the pixel 20 emits light in the first and second frames SF1 and SF2 on the basis of the supplied data current Imax and stops emitting light in the third to sixth sub-frames SF3 to SF6. In this case, the light-emitting period T becomes T=TL1+TL2. Also, if the gray-scale data D has a gray-scale level 6, the pixel 20 emits light in the second and third frames SF2 and SF3 on the basis of the supplied data current Imax and stops emitting light in the first and fourth to sixth sub-frames SF1 and SF4 to SF6. In this case, the light-emitting period T becomes T=TL2+TL3. That is, the largest data current Imax corresponding to the gray-scale level 63 is supplied to the data lines X1 to Xm and the light-emitting period T is changed according to the gray-scale data so that the pixel 20 externally emits light with the brightness corresponding to the gray-scale data D.

That is, in the organic electroluminescent display device 10 of the present embodiment, the gray-scale level is controlled by supplying the constant driving current and varying the period of supplying the driving current so that the organic electroluminescent element (electro-optical element) is driven. Furthermore, the driving circuit composed of elements (except the organic electroluminescent element 21) included in the above-mentioned pixel 20 is an example of a circuit for realizing the driving and the invention is not limited thereto. Furthermore, the first scan line Yn1, the second scan line Yn2, and the data line Xm correspond to the signal lines for supplying the signals from the outside to the driving circuit.

The organic electroluminescent display device 10 of the present embodiment has the above-mentioned structure. Next, the content of the signal delay and the structure for avoiding the same will be described.

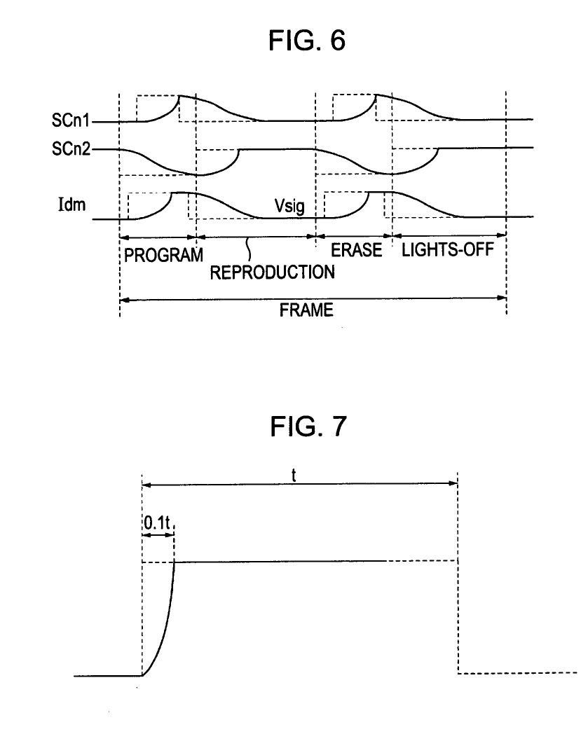

FIGS. 6 and 7 are views illustrating the content of signal delay. FIG. 6 shows the content corresponding to FIG. 4 and the waveforms of the signals having ideal states shown in FIG. 4 are shown by dot-lines. Furthermore, when the signal delay is generated by increasing the time constant of the signal line, the waveform of the signal is shown by solid lines. As shown, as the display panel 11 is enlarged, the signal delay increases according to the time constant increment of the signal line. If such a signal delay is generated, the display quality deteriorates.

Accordingly, in the present embodiment, the time constant determined by the resistance component and the capacitance component generated by the corresponding signal lines is set so that the delay of the signal supplied through each of the signal lines (the first scan line Yn1, the second scan line Yn2, and the data line Xm) becomes 10% or less. In the present embodiment, as shown in FIG. 7, if the rising time of the signal waveform (dotted-line) having the ideal state is t, the time constant of the signal line capable of transmitting the corresponding signal is set so that the rising delay time of the signal waveform due to the signal delay becomes 0.1 t.

The time constant can be set by increasing/decreasing the resistance component using a thickness and/or a line width of each of the signal lines as a parameter or by increasing/decreasing the resistance component using the specific resistance of the material used for forming each of the signal lines as a parameter. Since it is necessary to reduce the time constant in order to suppress the signal delay, the thickness or the line width of the signal line may increase or the material having a small specific resistance (for example, Al, AlZr, etc.) may be selected.

The time constant can be set by increasing/decreasing the capacitance component using a distance between adjacent signal lines as a parameter, by increasing/decreasing the capacitance component using a relative dielectric constant of the material used for forming an insulating film disposed at a lower layer and/or an upper layer of the signal line as a parameter, or by increasing/decreasing the capacitance component using a thickness the insulating film disposed at the lower layer and/or the upper layer of the signal line as a parameter. It is necessary to reduce the time constant in order to suppress the signal delay. Therefore, the distance between the signal lines may increase, the area of the signal line may decrease, the insulating film may be formed of the material having a low relative dielectric constant or the thickness of the insulting film may decrease.

Next, a method of manufacturing the organic electroluminescent display device 10 will be described while particularly focusing attention on a method of forming the signal line.

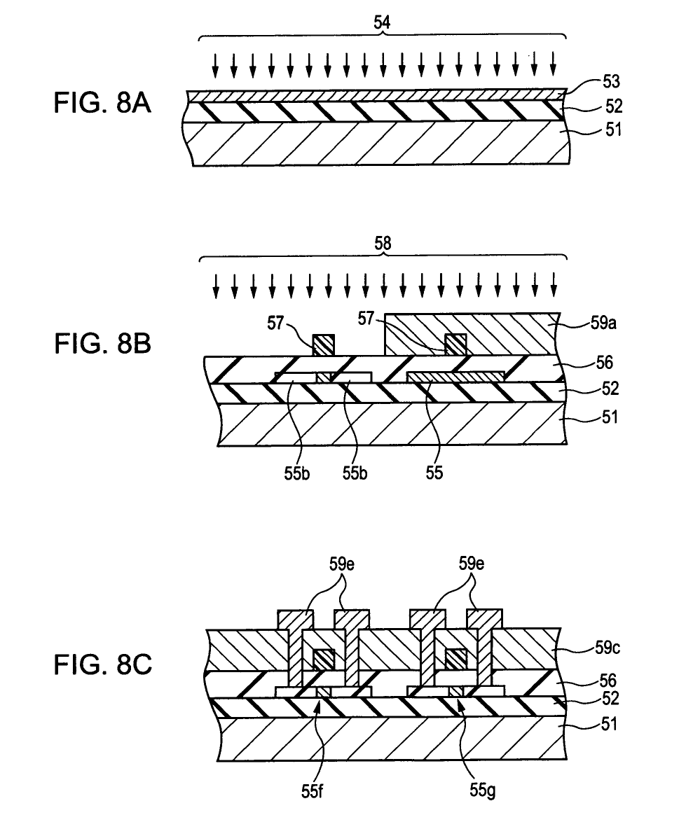

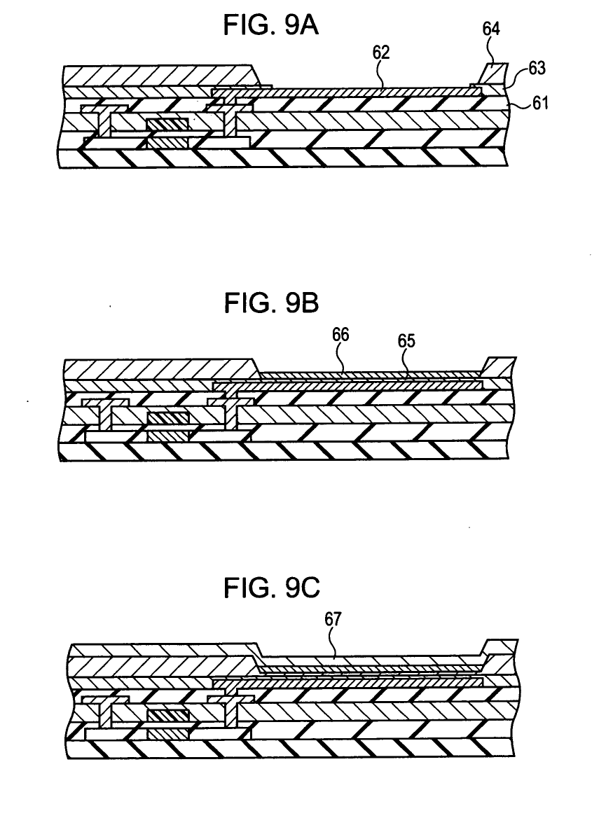

FIGS. 8 and 9 are process views illustrating a method of manufacturing the organic electroluminescent display device 10.

First, as shown in FIG. 8A, an underlying insulating film 52 is formed on a first substrate 51. As the underlying insulating film 52, for example, an oxide silicon film is preferably used. Next, a semiconductor film 53 is formed on the underlying insulating film 52 by a PECVD (plasma excitation chemical vapor deposition) method using SiH4 as a material gas or by a LPCVD (low pressure chemical vapor deposition) method using Si₂H₆ as a material gas. As the semiconductor film 53, for example, an amorphous silicon (a-Si) film is preferably used. Then, the semiconductor film 53 is crystallized by irradiating laser light 54. In the present embodiment, a polysilicon (poly-Si) film is obtained by crystallization. Subsequently, the semiconductor film 53 is patterned in a desired shape to obtain an active layer 55.

Next, as shown in FIG. 8B, a gate insulating film 56 is formed by a method such as a PECVD method using tetraethoxysilane (TEOS) as a material gas or an ECR-CVD (electron cyclotron resonance chemical vapor deposition) method. Subsequently, a conductive film having a low resistance is formed on the gate insulating film 56 and is patterned to form a gate electrode 57 and gate wiring lines (not shown). In the invention, as the conductive film having the low resistance, for example, a material having a specific resistance of 10 μΩ·m or less, such as Al or AlZr, is preferably used. After that, phosphorous ions or boron ions are selectively injected using a resist mask 57 by ion implantation or ion doping 58 to form source/drain regions 55b.

Next, as shown in FIG. 8C, a first interlayer insulating film 59c is formed and a contact hole is formed. Subsequently, a conductive film such as a metal film is formed on the first interlayer insulating film 59c and in the contact hole, and is patterned to form the source/drain electrode 59e and wiring lines (not shown).

The wiring lines connected to the above-mentioned source/drain electrode 59e or the gate wiring line functions as the signal lines, that is, the first scan line, the second scan line, or the data line. Accordingly, when the signal line is formed, the time constant of each of the signal lines becomes an adequate value by setting each of the above-mentioned parameters so as to increase/decrease the resistance component and the capacitance component.

Next, as shown in FIG. 9A, a second interlayer insulating film 61 is formed and a contact hole is formed. Subsequently, a transparent conductive film (ITO film) is formed on the second interlayer insulating film 61 and in the contact hole to obtain a positive electrode 62. A lyophilic material is formed and opened to obtain a lyophilic bank 63. A lyophobic material is formed and is opened to obtain a lyophobic bank 64. Next, as shown in FIG. 9B, polyethylenedioxythiophene (PEDOT) is coated by an inkjet method (droplet ejecting method) to form a hole-transporting layer 65 and a light-emitting material is coated to form a light-emitting layer 66. Subsequently, as shown in FIG. 9C, metal having a low work function is formed by a mask deposition method to obtain a negative electrode 67.

### Second Embodiment

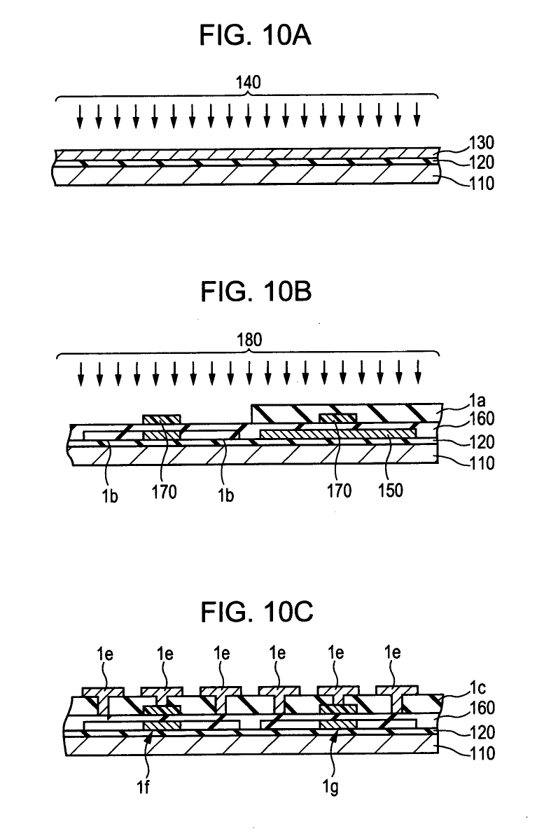

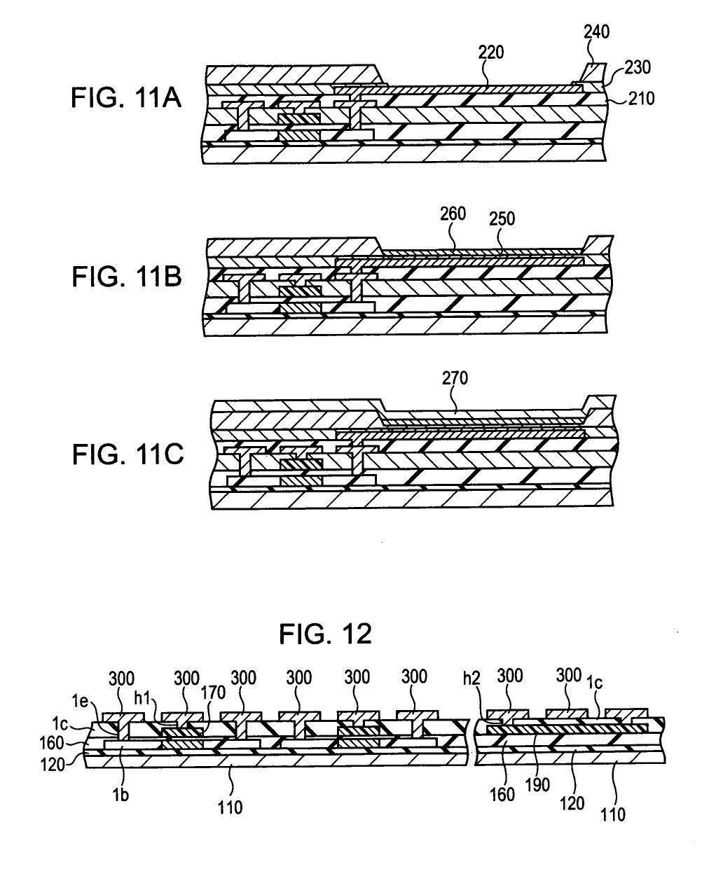

Next, a method of manufacturing the organic electroluminescent display device of the present embodiment will be described with reference to FIGS. 10 and 11.

FIG. 10 is a cross-sectional view showing processes of manufacturing a functional element. Here, the first functional element is a thin film transistor. First, as shown in FIG. 10A, an underlying insulating film 120 is formed on a first substrate 110. As the underlying insulating film 120, for example, an oxide silicon film is preferably used. Next, a semiconductor film 130 is formed on the underlying insulating film 120 by a PECVD (plasma excitation chemical vapor deposition) method using SiH4 as a material gas or a LPCVD (low pressure chemical vapor deposition) method using Si₂H₆ as a material gas. As the semiconductor film 130, for example, an amorphous silicon (a-Si) film is preferably used. After that, the semiconductor film 130 is crystallized by irradiating laser light 140. In the present embodiment, a polysilicon (poly-Si) film is obtained by the crystallization. Subsequently, the semiconductor film 130 is patterned in a desired shape to obtain an active layer 150.

Next, as shown in FIG. 10B, a gate insulating film 160 is formed by a method such as a PECVD method using tetraethoxysilane (TEOS) as a material gas or an ECR-CVD (electro cyclotron resonance chemical vapor deposition) method. Subsequently, a conductive film is formed on the gate insulating film 160 and is patterned to form a gate electrode 170. After that, phosphorous ions or boron ions are selectively injected using a resist mask la by an ion implantation or ion doping 180 to form source/drain regions 1b.

Next, as shown in FIG. 10C, a first interlayer insulating film 1c is formed and a contact hole is formed. Subsequently, a conductive film such as metal is formed on the first interlayer insulating film 1c and in the contact hole and is patterned to form the source/drain electrode 1e and wiring lines (not shown). In the source/drain electrode layer consisting of the low resistance material, the first scan line Yn1, the second scan line Yn2 connected to the gate of the reproduction selection transistor Trep, and the data line Xm for supplying the erasing signal Vsig. Accordingly, a CMOS circuit including an n-type thin film transistor 1f and a p-type thin film transistor 1g is formed. Although only one element is shown in FIG. 10C, a plurality of elements may be actually arranged.

FIG. 11 is a cross-sectional view illustrating processes of manufacturing a second functional element. Here, the second functional element is an organic electroluminescent element. First, as shown in FIG. 11A, a second interlayer insulating film 210 is formed and a contact hole is formed. Subsequently, a transparent conductive film (ITO film) is formed on the second interlayer insulating film 210 and in the contact hole to obtain a positive electrode 220. A lyophilic material is formed and is opened to obtain a lyophilic bank 230. A lyophobic material is formed and is opened to obtain a lyophobic bank 240. Next, as shown in FIG. 11B, polyethylenedioxythiophene (PEDOT) is coated by an inkjet method (droplet ejecting method) to form a hole-transporting layer 250 and a light emitting material is coated to form a light-emitting layer 260. Subsequently, as shown in FIG. 11C, metal having low work function is formed by a mask deposition method to obtain a negative electrode 270.

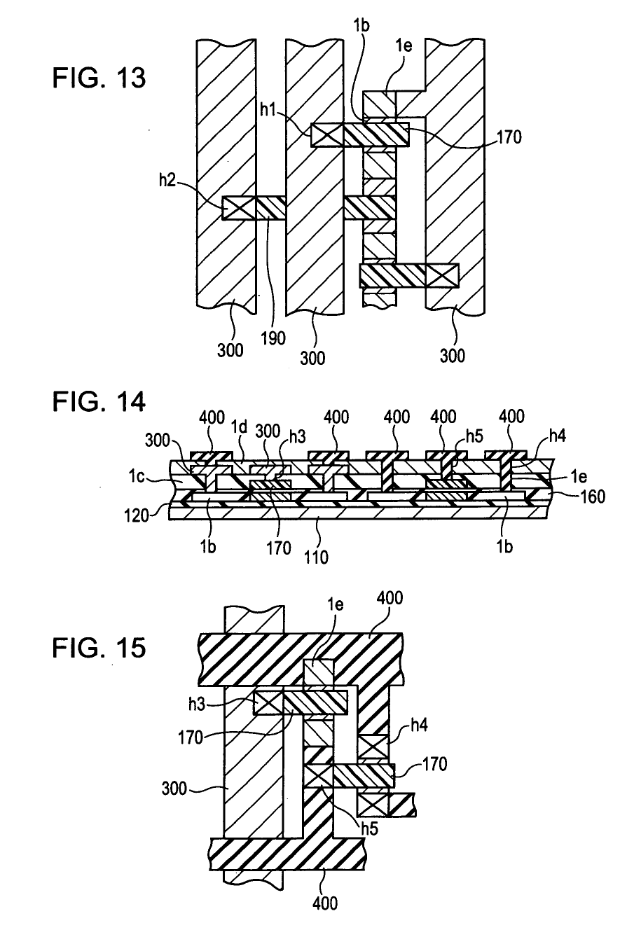

FIG. 12 is a cross-sectional view of a wiring substrate including a wiring layer of a single layer structure, and FIG. 13 is a wiring layout diagram of the wiring substrate. The layers having the same as those shown in FIG. 10 represent the same layers and the detailed description thereof is omitted. A first wiring layer 300 is formed on the first layer insulating film 1c. The first wiring layer 300 is composed of a plurality of wiring lines extending in the same direction. The gate electrode 170 and the wiring layer 300 are connected to each other through a contact hole h1. Furthermore, the gate electrode 170 and the wiring line 190, which is laid in the same layer as the gate electrode 170, are connected to each other through a contact hole h2. The above-mentioned first scan line Yn1, second scan line Yn2, and the data line Xm are formed by the first wiring layer 300. The time constant of the first wiring layer 300 is set so that the signal delay becomes 10% or less.

FIG. 14 is a cross-sectional view of a wiring substrate including a wiring layer of a double layer structure, and FIG. 15 is a wiring layout diagram of the wiring substrate. The layers having the same as those shown in FIG. 10 represent the same layers and the detailed description thereof is omitted. The first wiring layer 300 is formed on the first layer insulating film 1c. A second wiring layer 400 is additionally formed on the first wiring layer 300 through a second interlayer insulating film 1d. The second wiring layer 400 is composed of a plurality of wiring lines extending in the same direction. The wiring directions of the first wiring layer 300 and the second wiring layer 400 are substantially perpendicular to each other. The gate electrode 170 and the wiring layer 300 are connected to each other through a contact hole h3. The source/drain regions 1b and the second wiring layer 400 are connected to each other a contact hole h4. Also, the gate electrode 170 and the second wiring layer 400 are connected to each other a contact hole h5. The above-mentioned first scan line Yn1, second scan line Yn2, and the data line Xm are formed by the first wiring layer 300 or the second wiring layer 400. The time constant of the second wiring layer 400 is set so that the signal delay becomes 10% or less.

### Third Embodiment

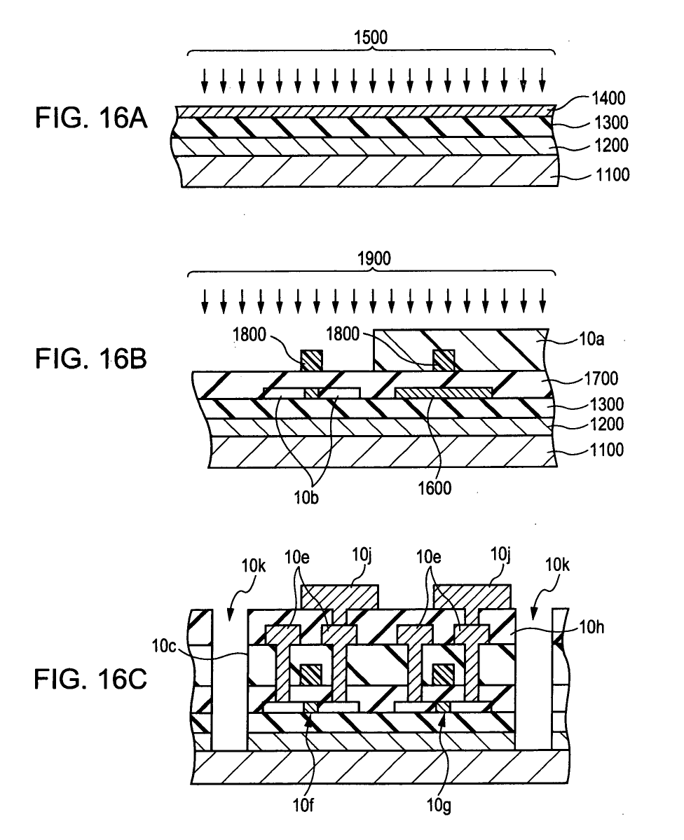

Next, a method of manufacturing an organic electroluminescent display device according to the present embodiment will be described with reference to FIGS. 16 to 19.

FIG. 16 is a process view illustrating a method of manufacturing an element chip including at least one first functional element. Here, the first functional element is a thin film transistor. As shown in FIG. 16A, a peeling layer 1200 is formed a temporary substrate 1100 and an underlying insulating film 1300 is formed thereon. Here, the peeling layer has a property that variation occurs by applying energy (for example, the irradiation of laser) to weaken the fixing degree between the temporary substrate 1100 and/or the underlying insulating film 1300, and is preferably formed of, for example, amorphous silicon. Next, a semiconductor film 1400 is formed on the underlying insulating film 1300 by a PECVD method using SiH4 as a material gas or a LPCVD method using Si₂H₆ as a material gas. As the semiconductor film 1400, for example, an amorphous silicon film is preferably used. After that, the semiconductor film 1400 is crystallized by irradiating laser light 1500. In the present embodiment, a polysilicon is obtained by the crystallization. Subsequently, the semiconductor film 1400 is patterned in a desired shape to obtain an active layer 1600.

Next, as shown in FIG. 16B, a gate insulating film 1700 is formed by a method such as a PECVD method using TEOS as a material gas or an ECR-CVD method. Subsequently, a conductive film such as metal is formed on the gate insulating film 1700 and is patterned to form a gate electrode 1800. After that, phosphorous ions or boron ions are selectively injected using a resist mask 10a by an ion implantation or ion doping 1900 to form source/drain regions 10b.

Next, as shown in FIG. 16C, a first interlayer insulating film 10c is formed and a first contact hole is formed. Subsequently, a conductive film such as metal is formed on the first interlayer insulating film 10c and in the contact hole and is patterned to form the source/drain electrode 10e and wiring lines (not shown). Accordingly, a CMOS circuit including an n-type thin film transistor 10f and a p-type thin film transistor 10g is formed. Also, a second interlayer insulating film 10h is formed and a contact hole is formed. Next, pad metal is formed on the second interlayer insulating film 10h and in the contact hole and is patterned to obtain connection pads 10j. Finally, a separation 10k for separating the element chip is formed. In FIG. 16C, although only one element chip is shown, a plurality of element chips may be actually arranged.

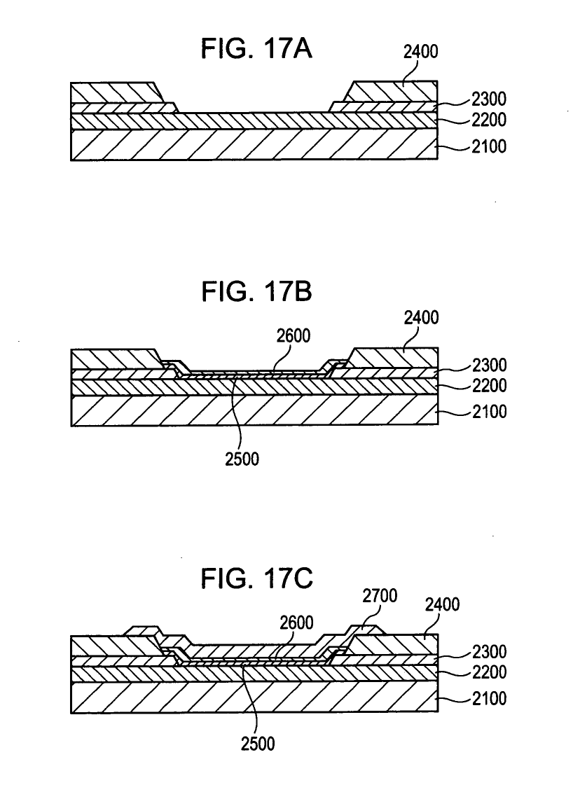

FIG. 17 is a process view illustrating a method of manufacturing a second functional element. Here, the second functional element is an organic electroluminescent element. First, as shown in FIG. 17A, a transparent conductive film (ITO film) is formed on a second substrate 2100 to obtain a positive electrode 2200. A lyophilic material is formed and opened to obtain a lyophilic bank 2300. A lyophobic material is formed and is opened to obtain a lyophobic bank 2400. Next, as shown in FIG. 17B, PSS(polystyrenesulfonate) doped polyethylenedioxythiophene (PEDOT) is coated by an inkjet method (droplet ejecting method) to form a hole-transporting layer 2500, and a light emitting material is coated to form a light-emitting layer 2600. Subsequently, as shown in FIG. 17C, metal having low work function is formed by a mask deposition method to obtain a negative electrode 2700.

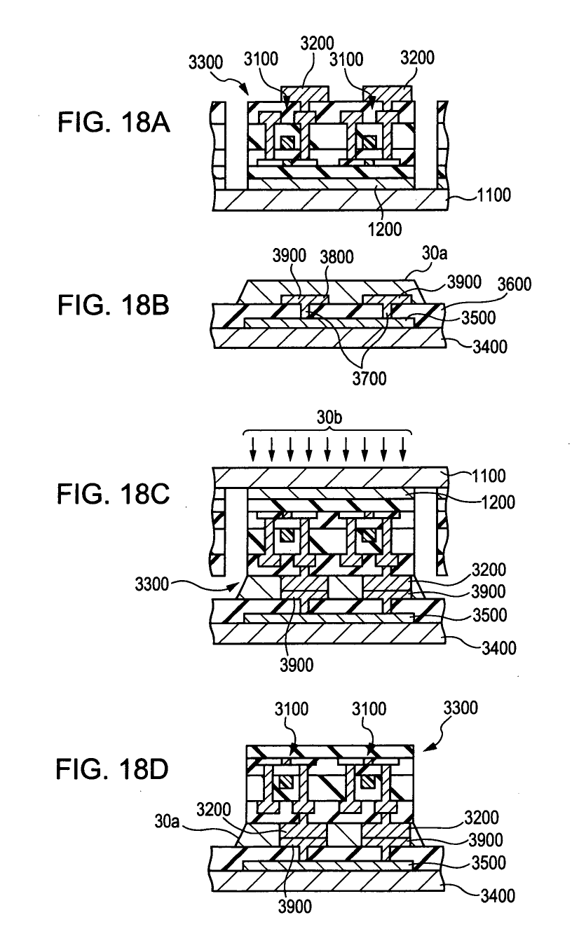

FIG. 18 is a process view illustrating a method of sacrificial peeling and transferring an element chip including at least one first functional element. As shown in FIG. 18A, a peeling layer 1200 is formed on a temporary substrate 1100, and a functional element 3100 and a connection pad 3200 are formed thereon to form an element chip 3300. Next, as shown in FIG. 18B, a first wiring line 3500 composed of a conductive film having a low resistance is formed, an interlayer insulating film 3600 is formed on the first wiring line 3500, and first contact holes 3700 are formed. Next, a second wiring line 3800 composed of a conductive film having a low resistance is formed. The second wiring line 3800 includes a connection pad 3900 for connection with the element chip 3300. Next, an adhesive 30a is coated on the connection pad 3900. Next, as shown in FIG. 18C, the upper surface of the temporary substrate 1100 and the upper surface of a third substrate 3400 contact with each other and are adhered to each other. The temporary substrate 1100 and the third substrate 3400 are pressed so that the connection pad 3200 of the element chip 3300 and the connection pad 3900 of the third substrate 3400 are electrically connected to each other using the adhesive 30a. After that, laser light 30b is irradiated to a peeling layer 1200 from the rear surface of the temporary substrate 1100 to peel the peeling layer 1200 by laser ablation. Then, the element chip 3300 including at least one third functional element 3100 is peeled from the temporary substrate 1100. Subsequently, as shown in FIG. 18D, the element chip 3300 is connected to the connection pad 3200 of the element chip 3300 including at least one thin film transistor 3100 and the connection pad 3900 of the third substrate 3400 having the first wiring line 3500 and the second wiring line 3800 formed thereon.

FIG. 19 illustrates the state that a third substrate 4100 connected with the element chip 3300 is bonded to a second substrate 4300. The connection pad 4200 formed on the third substrate 4100 and a negative electrode 4400 formed on the second functional element (organic electroluminescent element) of the second substrate 4300 are bonded to each other by a conductive paste 4500 formed on the connection pad 4200 using a screen printing to connect the connection pad 4200 of the third substrate with the negative electrode 4400 formed on the second functional element. Furthermore, the conductive paste 4500 may be formed on the negative electrode 4400 formed on the second functional element by the screen printing to connect the negative electrode 4400 with the connection pad 4200 of the third substrate.

In the organic electroluminescent device 10 of the present embodiment, the signal delay is suppressed by adequately setting the time constant of the signal line on the basis of the knowledge that allowable range of the signal delay is about 10% or less. Accordingly, writing lack of the signal required for the display control can be avoided at a maximum and thus the display quality can be prevented from being deteriorated by the signal delay.

### Fourth Embodiment

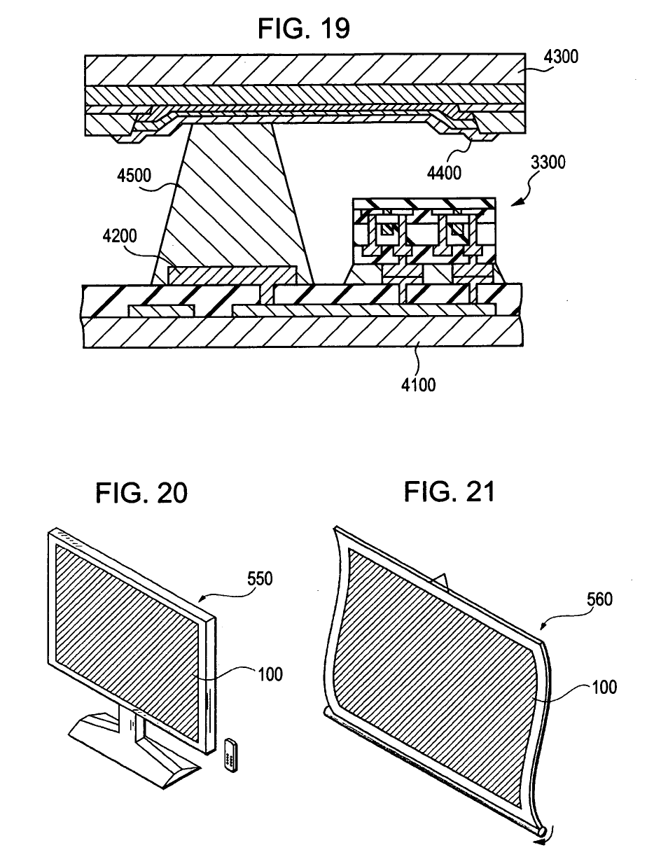

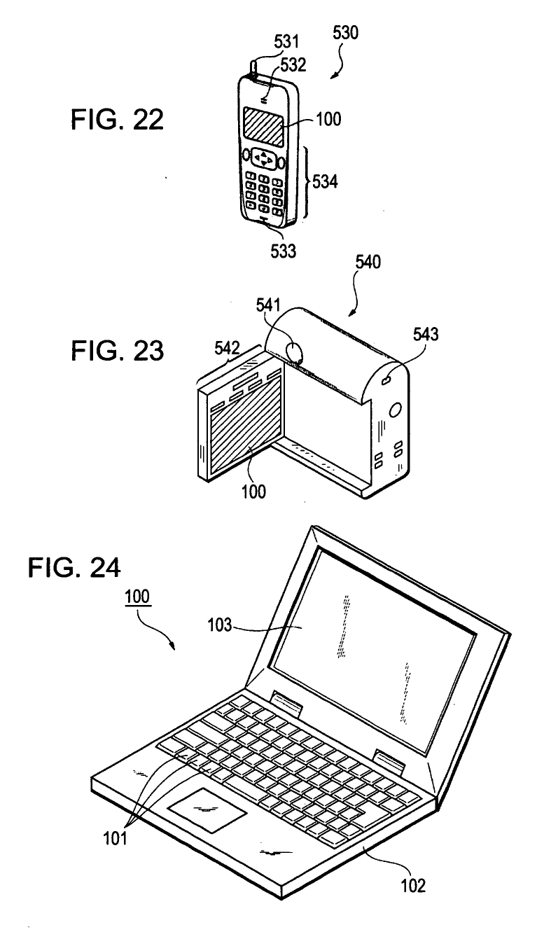

Next, specific examples of an electronic apparatus including the electro-optical device 100 will be described with reference to FIGS. 20 to 24. FIG. 20 illustrates an example of applying the electro-optical device to a television. A television 550 includes the electro-optical device 100 according to the invention. FIG. 21 illustrates an example of applying the electro-optical device to a roll-up type television. The roll-up type television 560 includes the electro-optical device according to the invention. FIG. 22 illustrates an example of applying the electro-optical device to a mobile phone. The mobile phone 530 includes an antenna unit 531, a sound output unit 532, a sound input unit 533, an operation unit 534, and the electro-optical device according to the invention. FIG. 23 illustrates an example of applying the electro-optical device to a video camera. The video camera 540 includes an image receiving unit 541, an operation unit 542, a sound input unit 543, and the electro-optical device according to the invention. FIG. 24 illustrates an example of applying the electro-optical device to a mobile type personal computer. The mobile type personal computer 100 includes a main body 102 including a keyboard 101 and a display unit 103 using the organic electroluminescent display device 10.

Further, the electronic apparatus is not limited thereto and can be various electronic apparatuses having the display function. For example, there are a facsimile having the display function, a finder of a digital camera, a portable television, an electronic notebook, an electric sign board, and an advertising display. Furthermore, the invention is not limited to the above-mentioned embodiments and various modifications can be made in the scope of the invention. For example, although the organic electroluminescent element is illustrated as the electro-optical device in the above-mentioned embodiments, the invention is not limited thereto. For example, the invention can be applied to various electro-optical devices (display device) such as an inorganic electroluminescent element, a liquid crystal element, a digital micro-mirror device (DMD), a field emission display (FED), and a surface-conduction electron-emitter display (SED).

What is claimed is:

1. An electro-optical device which has a program period, a light-emitting period, an erasing period, and a lights-off period in one frame and controls the light-emitting period according to a light emission gray-scale level, comprising:
a driving transistor that includes a current control terminal, a current input terminal, and a current output terminal, and controls a current amplifying ratio on the basis of a voltage between the current control terminal and the current input terminal;
an electro-optical element that is supplied with the driving current from the driving transistor to emit light;
a storage capacitor that stores the charge corresponding to the voltage between the current control terminal and the current input terminal of the driving transistor;
a constant current source that outputs a constant current that is independent of the light emission gray-scale level;
a voltage source that outputs a driving stop signal that turns off the driving transistor;
a selection transistor that opens/closes a current path connecting any one of the constant current source and the voltage source with the driving transistor; and
a scan line that outputs open/close signals that turn on/off the selection transistor,
wherein the program period is a period when the selection transistor is turned on by outputting an open signal to the scan line, and when the constant current flows from the constant current source to the driving transistor through the current path, the charge corresponding to the voltage between the current control terminal and the current input terminal is stored in the storage capacitor,
the light-emitting period is a period when the selection transistor is turned off by outputting a close signal to the scan line, and the voltage corresponding to the charge stored in the storage capacitor is supplied between the current control terminal and the current input terminal of the driving transistor to supply the driving current to the electro-optical element,
the erasing period is a period when the selection transistor is turned on by outputting the open signal to the scan line, and the driving stop signal is supplied to the driving transistor from the voltage source through the current path to turn off the driving transistor so that the electro-optical element stops emitting light,
the lights-off period is a period when the selection transistor is turned off by outputting the close signal to the scan line, and a the electro-optical element retains a non-light-emitting state, and
the time constant of the scan line is set so that the signal delay of the open/close signals is 10% or less of a theoretical value.

2. The electro-optical device according to claim 1,
wherein the time constant of the scan line is set by increasing/decreasing a resistance component using a thickness and/or a line width of the scan line as a parameter.

3. The electro-optical device according to claim 1,
wherein the time constant of the scan line is set by increasing/decreasing a resistance component using the specific resistance of a material used for forming the scan line as a parameter.

4. The electro-optical device according to claim 1,
wherein the time constant of the scan line is set by increasing/decreasing a capacitance component using a distance between adjacent scan lines as a parameter.

5. The electro-optical device according to claim 1,
wherein the time constant of the scan line is set by increasing/decreasing a capacitance component using a relative dielectric constant of a material used for forming an insulating film arranged above and/or below the scan line as a parameter.

6. The electro-optical device according to claim 1,
wherein the time constant of the scan line is set by increasing/decreasing a capacitance component using a thickness of a material used for forming an insulating film arranged above and/or below the scan line as a parameter.

7. An electro-optical device which has a program period, a light-emitting period, an erasing period, and a lights-off period in one frame and controls the light-emitting period according to a light emission gray-scale level, comprising:
a driving transistor that includes a current control terminal, a current input terminal, and a current output terminal, and controls a current amplifying ratio on the basis of a voltage between the current control terminal and the current input terminal;
an electro-optical element that is supplied with the driving current from the driving transistor to emit light;
a storage capacitor that stores the charge corresponding to the voltage between the current control terminal and the current input terminal of the driving transistor;
a constant current source that outputs a constant current that is independent of the light emission gray-scale level;
a voltage source that outputs a driving stop signal that turns off the driving transistor;
a selection transistor that opens/closes a data line connecting any either the constant current source or the voltage source with the driving transistor; and
a first scan line that outputs open/close signals that turn on/off the selection transistor,
wherein the program period is a period when the selection transistor is turned on by outputting an open signal to the first scan line, and when the constant current flows from the constant current source to the driving transistor through the data line, the charge corresponding to the voltage between the current control terminal and the current input terminal is stored in the storage capacitor,
the light-emitting period is a period when the selection transistor is turned off by outputting a close signal to the first scan line, and the voltage corresponding to the charge stored in the storage capacitor is supplied between the current control terminal and the current input terminal of the driving transistor to supply the driving current to the electro-optical element,
the erasing period is a period when the selection transistor is turned on by outputting the open signal to the first scan line, and the driving stop signal is supplied to the driving transistor from the voltage source through the current path to turn off the driving transistor so that the electro-optical element stops emitting light,
the lights-off period is a period when the selection transistor is turned off by outputting the close signal to the first scan line, and the electro-optical element retains a non-light-emitting state, and
the first scan line is formed by one or a plurality of wiring layers having a time constant in which the signal delay of the open/close signals is 10% or less of a theoretical value, and
the current control terminal of the selection transistor is connected to one or a plurality of wiring layers.

8. The electro-optical device according to claim 7, further comprising:
a reproduction selection transistor that opens/closes a current path supplying the driving current from the driving transistor to the electro-optical element; and
a second scan line that outputs an open/close signal that turns on/off the reproduction selection transistor,
wherein the second scan line is formed by one or a plurality of wiring layers having a time constant in which the signal delay of the open/close signals is 10% or less of a theoretical value, and
a current control terminal of the reproduction selection transistor is connected to one or a plurality of wiring layers.

9. The electro-optical device according to claim 7,
wherein the data line is formed by one or a plurality of wiring layers having a time constant in which the signal delay of the open/close signals is 10% or less of a theoretical value, and
the current output terminal of the driving transistor is connected to one or a plurality of wiring layers.

10. The electro-optical device according to claim 7,
wherein the time constant of the wiring layer is set by increasing/decreasing a resistance component using a thickness and/or a line width of the first scan line, the second scan line, or the data line as a parameter.

11. The electro-optical device according to claim 7,
wherein the time constant of the wiring layer is set by increasing/decreasing a resistance component using the specific resistance of a material used for forming the first scan line, the second scan line, or the data line as a parameter.

12. The electro-optical device according to claim 1,
wherein the time constant of the wiring layer is set by increasing/decreasing a capacitance component using a distance between adjacent first scan lines, adjacent second scan lines, or adjacent data lines as a parameter.

13. The electro-optical device according to claim 1,
wherein the time constant of the wiring layer is set by increasing/decreasing a capacitance component using a relative dielectric constant of a material used for forming an insulating film arranged above and/or below the first scan line, the second scan line, or the data line as a parameter.

14. The electro-optical device according to claim 1,
wherein the time constant of the wiring layer is set by increasing/decreasing a capacitance component using a thickness of a material used for forming an insulating film arranged above and/or below the first scan line, the second scan line, or the data line as a parameter.

15. The electro-optical device according to claim 1,
wherein the electro-optical element is an organic electroluminescent element.

16. An electronic apparatus comprising the electro-optical device according to claim 1.

17. A method of manufacturing an electro-optical device comprising:
a driving transistor that includes a current control terminal, a current input terminal, and a current output terminal, and controls a current amplifying ratio on the basis of a voltage between the current control terminal and the current input terminal;
an electro-optical element that is supplied with the driving current from the driving transistor to emit light;
a storage capacitor that stores the charge corresponding to the voltage between the current control terminal and the current input terminal of the driving transistor;
a constant current source that outputs a constant independent of the light emission gray-scale level;
a voltage source that outputs a driving stop signal that turns off the driving transistor;
a selection transistor that opens/closes a current path connecting any one of the constant current source and the voltage source with the driving transistor; and
a scan line that outputs open/close signals that turn on/off the selection transistor,
in which one frame has a program period, a light-emitting period, an erasing period, and a lights-off period, and the light-emitting period is controlled according to a light emission gray-scale level,
the program period is a period when the selection transistor is turned on by outputting an open signal to the scan line, and when the constant current flows from the constant current source to the driving transistor through the current path, the charge corresponding to the voltage between the current control terminal and the current input terminal is stored in the storage capacitor,
the light-emitting period is a period when the selection transistor is turned off by outputting a close signal to the scan line, and the voltage corresponding to the charge stored in the storage capacitor is supplied between the current control terminal and the current input terminal of the driving transistor to supply the driving current to the electro-optical element,
the erasing period is a period when the selection transistor is turned on by outputting the open signal to the scan line, and the driving stop signal is supplied to the driving transistor from the voltage source through the current path to turn off the driving transistor so that the electro-optical element stops emitting light,
the lights-off period is a period when the selection transistor is turned off by outputting the close signal to the scan line, and the electro-optical element retains a non-light-emitting state, and
the time constant of the scan line is set so that the signal delay of the open/close signals is 10% or less of a theoretical value, the method comprising:
forming the driving transistor on a temporary substrate;
forming a signal line which connects the driving transistor with the electro-optical element on a wiring substrate; and
bonding the driving transistor to the wiring substrate to connect the driving transistor with the signal line.

18. The method of manufacturing an electro-optical device according to claim 17,
wherein the time constant of the scan line is set by increasing/decreasing a resistance component using a thickness and/or a line width of the scan line as a parameter.

19. The method of manufacturing an electro-optical device according to claim 17,
wherein the time constant of the scan line is set by increasing/decreasing a resistance component using the specific resistance of a material used for forming the scan line as a parameter.

20. The method of manufacturing an electro-optical device according to claim 17,
wherein the time constant of the scan line is set by increasing/decreasing a capacitance component using a distance between adjacent scan lines as a parameter.

21. The method of manufacturing an electro-optical device according to claim 17,
wherein the time constant of the scan line is set by increasing/decreasing a capacitance component using a relative dielectric constant of a material used for forming an insulating film arranged above and/or below the scan line as a parameter.

22. The method of manufacturing an electro-optical device according to claim 17,
wherein the time constant of the scan line is set by increasing/decreasing a capacitance component using a thickness of a material used for forming an insulating film arranged above and/or below the scan line as a parameter.

23. The method of manufacturing an electro-optical device according to claim 17,
wherein the electro-optical element is an organic electroluminescent element.

24. An electronic apparatus comprising the electro-optical device manufactured by the method according to claim 17.
